(19) United States
(12) Patent Application Publication
(10) Pub. No.: US 2020/0400730 A1
(43) Pub. Date: Dec. 24, 2020

(54) FREQUENCY SPECTRUM MONITORING DATA STRUCTURED REPRESENTATION METHOD, AND DATA PROCESSING METHOD AND COMPRESSION METHOD

(71) Applicant: XI'AN DAHENG TIANCHENG IT CO., LTD., Xi'an City, Shaanxi Province (CN)

(72) Inventors: Hong YOU, Xi'an (CN); Hongguang MA, Xi'an (CN)

(21) Appl. No.: 16/979,112

(22) PCT Filed: Feb. 21, 2019
(86) PCT No.: PCT/CN2019/075666

§ 371 Date: Sep. 8, 2020

(30) Foreign Application Priority Data
Mar. 6, 2018 (CN) 201810181414.7
Mar. 6, 2018 (CN) 201810181415.1

(51) Int. Cl. G01R 23/16; G01R 23/02; G06F 16/174

(52) U.S. Cl. CPC G01R 23/16; G06F 2216/03; G06F 16/1744; G01R 23/02

(57) ABSTRACT

Provided is a frequency spectrum monitoring data structured representation method, comprising the following steps: discretizing frequency spectrum monitoring data of a single station in a time dimension and a frequency spectrum dimension to form a two-dimensional frequency spectrum matrix; and arranging frequency spectrum matrices, obtained by all the stations in a certain region, according to a certain rule by taking a certain point as the center, so as to construct a three-dimensional frequency spectrum matrix body. The positive effects of the present invention are that: four dimensions, i.e. time, frequency spectrum, space and energy, of frequency spectrum data can be associated to form a structured organization system meeting frequency spectrum monitoring data; a mathematical operation can be further defined for a frequency spectrum matrix and a frequency spectrum matrix body, thereby conveniently performing information mining on massive monitoring data; and subsequent compression processing and remote transmission of the monitoring data can be facilitated, and requirements of frequency spectrum monitoring station network system construction and big data processing are better met, so that the frequency spectrum monitoring data is utilized more rationally and efficiently.

### BACKGROUND OF THE PRESENT INVENTION

### Field of Invention

The present invention relates to the technical field of radio spectrum monitoring data processing, and particularly relates to a structured representation method and data processing method for spectrum monitoring data.

### Description of Related Arts

Due to the development of information technology, electromagnetic spectrum resources are becoming more and more tense, and it is more and more important to strengthen electromagnetic spectrum management. Monitoring the use of electromagnetic spectrum resources is an important means of electromagnetic spectrum management. However, due to the large number of electromagnetic spectrum monitoring fixed stations, mobile monitoring vehicles, and etc., and the requirement of uninterrupted continuous monitoring, these make electromagnetic spectrum monitoring data have the characteristics of geographically dispersed and massive data. Traditional spectrum monitoring data storage and processing methods are gradually difficult to adapt to the new requirements of electromagnetic spectrum data transmission and big data processing. The patent CNXXXXXXXXXXX.X (filing date XXXX-XX-XX) applied by this unit proposes a data processing system and method for how a single-spectrum monitoring station exchanges data with other stations, data centers and relay stations. The above system and method describe how to transmit data between stations and how to structure the monitoring data of a single station. However, it does not involve how to organize and structure the monitoring data of multiple geographically scattered stations in a certain area.

On the basis of the above-mentioned patents, the present invention further excavates the structural characteristics of the electromagnetic spectrum monitoring data of multiple stations. According to the information correlation of the spectrum data of multiple stations in the dimensions of time, frequency, position, and energy, a new structured representation method is proposed, and mathematical operations for structured representation of single-station and multi-station are also defined. The structured representation method provided by the present invention will facilitate in-depth information mining of massive monitoring data, facilitate subsequent compression processing and long-distance transmission of monitoring data, and be more suitable for the construction requirements of the spectrum monitoring station network system, making the spectrum monitoring data be used more reasonably and efficiently.

In addition, with the increasing importance and attention of spectrum resources, the number of electromagnetic spectrum stations has rapidly expanded. Processing electromagnetic spectrum monitoring data to obtain detailed spectrum usage status is the basis for reasonable and efficient spectrum resource utilization and spectrum management. In particular, with the development of the spectrum network construction, the demand for data transmission and processing between spectrum monitoring stations and different spectrum management units continues to increase. Because the natural characteristics of massive and scattered nature of spectrum monitoring data, the storage and processing methods of traditional spectrum monitoring data are gradually difficult to adapt to the new requirements for electromagnetic spectrum data transmission and big data processing. In the patent (CNxxxxxxxxx.x, filing date: 2018-XX-XX) applied by this unit, the spectrum monitoring data of a single station in the form of a spectrum matrix, which can be converted into a gray image for compression and transmission is disclosed. In the patent (CNxxxxxxxxx.x, filing date: 2018-XX-XX) disclosed a structured representation method of multi-station spectrum monitoring data, which is expressed as a spectrum matrix body. This structure is not only similar in form and structure to video data, but in terms of data characteristics, the spectrum monitoring data of multiple stations in a given area has a very strong correlation between data in the three dimensions of time, frequency, and position. For example, the spectrum monitoring data is highly correlated at adjacent monitoring times; the neighboring stations have strong correlations with the monitoring data obtained at different times; the adjacent frequency bands and monitoring data also have correlations. Therefore, the monitoring data expressed in the form of a spectrum matrix has a considerable degree of information redundancy.

### SUMMARY OF THE PRESENT INVENTION

In the first aspect which is based on the reference and development of existing methods and theories, the present invention provides a spectrum monitoring data structuring method for the data processing requirements of multiple electromagnetic spectrum monitoring stations. The system and method provided by the present invention can realize the standardized processing process of spectrum monitoring data, form a data processing flow that meets the requirements of the spectrum monitoring network system, and provide mathematical operations suitable for a given structured representation, which is beneficial to more reasonable and efficient use of monitoring data from multiple stations.

In order to accomplish the above objective, the technical solution of the present invention is:

A structured representation method of spectrum monitoring data, which comprises the following steps of:

S1: discretizing spectrum monitoring data of a single station in time dimension and frequency dimension to form a two-dimensional spectrum matrix;

S2: constructing a three-dimensional spectrum matrix by using the two-dimensional spectrum matrix obtained from all stations in a certain area, taking a certain point as a center, and aligning in a position dimension according to certain rules.

In the step S1, the two-dimensional spectrum matrix is formed by the following steps of:

S1.1: the spectrum monitoring station, according to a synchronization or calibration method, obtaining a synchronized clock with other stations, then obtaining a uniformly specified sampling time tₙ, spectrum bandwidth B and frequency sampling points M, where n is 1, 2, 3, . . . , N, N is a positive integer;

S1.2: at the sampling time tₙ, using the spectrum bandwidth B and the number of frequency sampling points M to discretize the monitoring data in the frequency dimension to obtain a vector Iₜ_{ₙ}, and a sequence Iₜᵣᵢ is 1×M dimension;

S1.3: for a given monitoring time period, at the sampling time tₙ, obtaining spectrum monitoring vectors at different sampling time Iₜ₁, Iₜ, . . . , Iₜ_{_{N}};

S1.4: aligning the spectrum monitoring vectors at different sampling time in chronological order to form a two-dimensional spectrum matrix W=[Iₜ_{₁} Iₜ_{₂} . . . Iₜ_{_{N}}]^{T}, the matrix W is N×M dimension.

In the step S1, the two-dimensional spectrum matrix can define the following mathematical operations:

(1) assume the two-dimensional frequency spectrum matrix is both of which are N×M dimension, then

Spectrum Matrix Addition:

$${W}_{i} + {W}_{j} = ( \begin{matrix}{x}_{11} & … & {x}_{1 N} \\ ⋮ & ⋱ & ⋮ \\ {x}_{M 1} & … & {x}_{NM}\end{matrix} ) + ( \begin{matrix}{y}_{11} & … & {y}_{1 N} \\ ⋮ & ⋱ & ⋮ \\ {y}_{M 1} & … & {y}_{NM}\end{matrix} ) = ( \begin{matrix}{x}_{11} + {y}_{11} & … & {x}_{1 N} + {y}_{1 N} \\ ⋮ & ⋱ & ⋮ \\ {x}_{M 1} + {y}_{M 1} & … & {x}_{NM} + {y}_{NM}\end{matrix} )$$

The spectrum matrix addition can be applied to obtain the sum of the spectrum data of multiple stations so as to obtain the overall average data of the spectrum usage condition in a certain area.

Spectrum Matrix Subtraction:

$${W}_{i} - {W}_{j} = ( \begin{matrix}{x}_{11} & … & {x}_{1 N} \\ ⋮ & ⋱ & ⋮ \\ {x}_{M 1} & … & {x}_{NM}\end{matrix} ) - ( \begin{matrix}{y}_{11} & … & {y}_{1 N} \\ ⋮ & ⋱ & ⋮ \\ {y}_{M 1} & … & {y}_{NM}\end{matrix} ) = ( \begin{matrix}{x}_{11} - {y}_{11} & … & {x}_{1 N} - {y}_{1 N} \\ ⋮ & ⋱ & ⋮ \\ {x}_{M 1} - {y}_{M 1} & … & {x}_{NM} - {y}_{NM}\end{matrix} )$$

The spectrum matrix subtraction can be used to process subtraction between the spectrum data of multiple stations so as to obtain information on the difference in the spectrum usage condition between different stations; it can also be used to subtract the station monitoring data from the electromagnetic background data to obtain the monitoring data of a specific emitter.

(2) Frequency dimension projection of spectrum matrix:

$$FProj ( W ) = ( \begin{matrix}{\sum }_{i = 1}^{N} {x}_{1 i} \\ {\sum }_{i = 1}^{N} {x}_{2 i} \\ ⋮ \\ {\sum }_{i = 1}^{N} {x}_{Mi}\end{matrix} ) = ( \begin{matrix}{Z}_{1} \\ {Z}_{2} \\ ⋮ \\ {Z}_{M}\end{matrix} )$$

The frequency dimension projection of the spectrum matrix can obtain the average spectrum usage condition of a single station in a certain period of time.

(3) Time dimension projection of spectrum matrix:

$$TProj ( W ) = ( \begin{matrix}{\sum }_{i = 1}^{M} {x}_{i 1} & {\sum }_{i = 1}^{M} {x}_{i 2} & … & {\sum }_{i = 1}^{M} {x}_{iN}\end{matrix} ) = ( \begin{matrix}{L}_{1} & {L}_{2} & … & {L}_{N}\end{matrix} )$$

The frequency dimension projection of the spectrum matrix can obtain the time occupancy of a single station in a given spectrum segment.

(4) m is a real number, then multiply the spectrum matrix number:

$$mW = ( \begin{matrix}{mx}_{11} & … & {mx}_{1 N} \\ ⋮ & ⋱ & ⋮ \\ {mx}_{M 1} & … & {mx}_{NM}\end{matrix} )$$

In the step S2, the three-dimensional spectrum matrix is constructed by the following steps:

S2.1: obtaining the monitoring data of all K spectrum monitoring stations in a certain area within a given time period, which are W₁, W₂, W . . . W_{K};

S2.2: According to the relationship between the positions of the K number of spectrum monitoring stations, arrange W₁, W₂, W_{K} to form a three-dimensional spectrum matrix body Q=[W₁, W₂, W_{K}]^{T}, the matrix body Q is N×M×K dimension.

In the step S2.2, the spectrum matrix body Q formed by the spectrum matrix W₁, W₂, W_{K} of the K number of spectrum monitoring stations employs the following steps and rules:

S2.2.1: Calculate a geometric center point V₀ on a geographical distribution according to latitude and longitude positions Vₙ of K number of spectrum monitoring stations, where n takes the value 1, 2, 3, . . . , K;

$${V}_{0} = \frac{1}{K} {\sum }_{i = 1}^{K} {V}_{i}$$

S2.2.2: Calculate the distance Dₙ between the latitude and longitude position Vₙ of each spectrum monitoring station and the geometric center point V₀, where ∥˜∥₂ is the second-order norm operation:

Dₙ=∥Vₙ−V₀∥₂

S2.2.3: according to the order from small to large of the distance Dₙ between the spectrum monitoring station and the geometric center point V₀, arrange the corresponding spectrum matrix of the station to construct the spectrum matrix body Q=[W₁, W₂, . . . W_{K}]^{T}.

In the step S2, the three-dimensional frequency spectrum matrix defines the following mathematical operations:

(1) Assuming that the spectrum matrices are Qᵢ and Qⱼ, both of which are NxMxK dimensions, then

Spectrum Matrix Addition:

Qᵢ+Qⱼ=[W₁ⁱ,W₂ⁱ, . . . W_{K}ⁱ]^{T}+[W₁^{j},W₂^{j}, . . . W_{K}^{j}]^{T}=[W₁ⁱ+W₁^{j},W₂ⁱ+W₂^{j}, . . . W_{K}ⁱ+W_{K}^{j}]^{T}

The spectrum matrix addition can be applied to obtain the sum of the spectrum data of multiple stations so as to obtain the overall average data of the spectrum usage condition in a larger area.

Spectrum Matrix Subtraction:

Qᵢ−Qⱼ=[W₁ⁱ,W₂ⁱ, . . . W_{K}ⁱ]^{T}−[W₁^{j},W₂^{j}, . . . W_{K}^{j}]^{T}=[W₁ⁱ−W₁^{j},W₂ⁱ−W₂^{j}, . . . W_{K}ⁱ−W_{K}^{j}]^{T}

The spectrum matrix subtraction can be used to process subtraction between the spectrum data of multiple stations so as to obtain information on the difference in the spectrum usage condition between different areas; it can also be used to subtract the area monitoring data from the area electromagnetic background data to obtain the monitoring data of a specific emitter of a specific area.

(2) Projection of Frequency Dimension of Spectrum Matrix:

FProj(Q)=[FProj(W₁),FProj(W₂), . . . FProj(W_{K})]^{T}

The projection of frequency dimension of the spectrum matrix can obtain a relationship between the spectrum usage condition and the geolocation of an area in a certain period of time.

(3) The projection of time dimension of the spectrum matrix

TProj(Q)=[TProj(W₁),TProj(W₂), . . . TProj(W_{K})]^{T}

The projection of time dimension of the spectrum matrix can obtain a relationship between the spectrum usage time and the geolocation of an area in a certain period of time.

(4) m is a real number, then multiplication operation of the spectrum matrix body is:

mQ=[mW₁,mW₂, . . . mw_{K}]^{T}

The present invention can correlate the four dimensions of time, spectrum, space and energy of spectrum data to form a structured organization system that conforms to spectrum monitoring data.

The present invention further defines mathematical operations for the spectrum matrix and the spectrum matrix body, so as to conveniently perform information mining on massive monitoring data.

The present invention is conducive to the subsequent compression processing and long-distance transmission of monitoring data, and is more suitable for the construction of spectrum monitoring station network and the requirements of big data processing, so that the spectrum monitoring data can be used more reasonably and efficiently.

In the second aspect, in view of the structured representation of the single-station spectrum matrix and the multi-station spectrum matrix system of spectrum monitoring data, the present invention provides a compression processing method for the multi-station spectrum monitoring data, which is based on the structured representation method of spectrum monitoring data, utilizes the similarity characteristics of the spectrum monitoring data of multiple stations in a given area, and draws reference to the principle of traditional video compression to process the massive spectrum monitoring data of multiple stations. The application prospects in the construction of wireless spectrum monitoring network system, data transmission, and big data processing are board, which is conducive to the more reasonable and efficient use of spectrum monitoring data of wireless station.

In order to accomplish the above objective, the technical solution of the present invention is to provide a compression processing method for spectrum monitoring data, which comprises the following steps of:

Structured representation of spectrum monitoring data of single station: according to a unified monitoring frequency bandwidth, monitoring a sampling interval of time dimension and a sampling interval of frequency dimension, completing discretization of the frequency dimension and discretization of the time dimension of the monitoring data in a given time period at a given time and a given bandwidth, expressing the spectrum monitoring data of the given monitoring time period and the frequency bandwidth as a spectrum matrix;

Structured representation of spectrum monitoring data of multiple stations: arranging all the spectrum matrices obtained by the multiple stations in a given area into a spectrum matrix body according to specific rules of the station position;

Gray-scale processing of spectrum monitoring data: selecting a dimension from the three dimensions of the spectrum matrix body, where the spectrum matrix body can be regarded as an arrangement of a series of matrices in the selected dimension, transforming each of the matrices into a grayscale image by gray-scale processing such that the spectrum matrix body can be regarded as a piece of video data;

Utilization of video compression method to compress monitoring data: for the monitoring data of multiple stations in a given area, there is a large amount of redundant information in the dimensions of time, frequency, and position, compressing the video data corresponding to the spectrum matrix body by using traditional video compression standards.

In the step of structured representation of spectrum monitoring data of multiple stations of the compression processing method for spectrum monitoring data in multiple stations, the arrangement of the spectrum matrices into the spectrum matrix body can adopt the following two methods:

Selecting a monitoring station as a reference station, and arranging the spectrum matrix data corresponding to each station based on a geographic straight-line distance between all stations and the reference point;

Selecting a geographic position corresponding to the average longitude and latitude of geographic locations of multiple stations in a certain area as a reference point, and arranging the spectrum matrix data corresponding to each station based on a geographic straight-line distance between all stations and the reference point.

In the step of gray-scale processing of spectrum monitoring data of the compression processing method for spectrum monitoring data in multiple stations, the spectrum matrix body can adopt the following three methods to carry out gray-scale processing:

Select the time dimension as the reference dimension such that the spectrum matrix body can be regarded as data arranged by a series of two-dimensional matrices corresponding to each time point; carry out grayscale processing on each matrix to convert each matrix into a grayscale image such that in the time dimension, and the spectrum matrix body can be regarded as a piece of video data. Obviously, the relationship of adjacent monitoring time and monitoring data is very strong.

Select the frequency dimension as the reference dimension such that the spectrum matrix body can be regarded as data arranged by a series of two-dimensional matrices corresponding to each time point; carrying out grayscale processing on each matrix to convert each matrix into a grayscale image such that in the time dimension, the spectrum matrix body can be regarded as a piece of video data. The adjacent frequency bands and monitoring data are also correlated.

Select the position dimension as the reference dimension such that the spectrum matrix body can be regarded as data arranged by a series of two-dimensional matrices corresponding to each time point; carrying out grayscale processing on each matrix to convert each matrix into a grayscale image such that in the time dimension, the spectrum matrix body can be regarded as a piece of video data. There is also strong correlation between the monitoring data obtained at different times between adjacent stations.

On the other hand, the present invention provides a processing method of spectrum monitoring data, which includes:

Arrange the two-dimensional spectrum matrices of multiple stations to form a three-dimensional spectrum matrix body according to the mutual relationship between the positions of the stations,

wherein the two-dimensional spectrum matrix of each station is formed by the discretization of the spectrum monitoring data of the station in the time and frequency dimensions.

Furthermore, the two-dimensional spectrum matrix of each station is formed by the following steps:

S1.1: obtaining a synchronized clock of one station with other stations, then obtaining a uniformly specified sampling time tₙ (1 . . . N), spectrum bandwidth B and frequency sampling points M;

S1.2: at the sampling time tₙ, using the spectrum bandwidth B and the frequency sampling points M to discretize the monitoring data in the frequency dimension to obtain a vector Iₜ_{ₙ}, and a sequence Iₜ_{ₙ} is 1×M dimension;

S1.3: for a given monitoring time period, at the sampling time tₙ, obtaining spectrum monitoring vectors at different sampling time Iₜ_{₁}, Iₜ_{₂}, . . . , Iₜ_{_{N}};

S1.4: aligning the spectrum monitoring vectors at different sampling time in chronological order to form a two-dimensional spectrum matrix W=[Iₜ_{₁} Iₜ_{₂} . . . Iₜ_{_{N}}]^{T}, the matrix W is N×M dimension.

Furthermore, when the total of the spectrum monitoring data of a station is required to be obtained, the two-dimensional spectrum matrix of the multiple stations is processed as follows:

$${W}_{i} + {W}_{j} = ( \begin{matrix}{x}_{11} + {y}_{11} & … & {x}_{1 N} + {y}_{1 N} \\ ⋮ & ⋱ & ⋮ \\ {x}_{M 1} + {y}_{M 1} & … & {x}_{NM} + {y}_{NM}\end{matrix} )$$

When the difference of the spectrum monitoring data of a station is required to be obtained, the two-dimensional spectrum matrix of the multiple stations is processed as follows:

$${W}_{i} - {W}_{j} = ( \begin{matrix}{x}_{11} - {y}_{11} & … & {x}_{1 N} - {y}_{1 N} \\ ⋮ & ⋱ & ⋮ \\ {x}_{M 1} - {y}_{M 1} & … & {x}_{NM} - {y}_{NM}\end{matrix} )$$

wherein,

$${W}_{i} = ( \begin{matrix}{x}_{11} & … & {x}_{1 N} \\ ⋮ & ⋱ & ⋮ \\ {x}_{M 1} & … & {x}_{NM}\end{matrix} ) , {W}_{j} = ( \begin{matrix}{y}_{11} & … & {y}_{1 N} \\ ⋮ & ⋱ & ⋮ \\ {y}_{M 1} & … & {y}_{NM}\end{matrix} )$$

When the usage condition of the spectrum monitoring data of a station in a certain period of time is required, the two-dimensional spectrum matrix of the station is processed as follows:

$$TProj ( W ) = ( \begin{matrix}{\sum }_{i = 1}^{M} {x}_{i 1} & {\sum }_{i = 1}^{M} {x}_{i 2} & … & {\sum }_{i = 1}^{M} {x}_{iN}\end{matrix} ) = ( \begin{matrix}{L}_{1} & {L}_{2} & … & {L}_{N}\end{matrix} )$$

When the spectrum evaluation usage of the spectrum monitoring data of a station in a certain frequency band is required, the two-dimensional spectrum matrix of the station is processed as follows:

$$FProj ( W ) = ( \begin{matrix}{\sum }_{i = 1}^{N} {x}_{1 i} \\ {\sum }_{i = 1}^{N} {x}_{2 i} \\ ⋮ \\ {\sum }_{i = 1}^{N} {x}_{Mi}\end{matrix} ) = ( \begin{matrix}{Z}_{1} \\ {Z}_{2} \\ ⋮ \\ {Z}_{M}\end{matrix} )$$

When the multiplication data of the spectrum monitoring data of a station is required, the two-dimensional spectrum matrix of the station is processed as follows:

$$mW = ( \begin{matrix}{mx}_{11} & … & {mx}_{1 N} \\ ⋮ & ⋱ & ⋮ \\ {mx}_{M 1} & … & {mx}_{NM}\end{matrix} )$$

wherein, m is a real number.

Furthermore, a geometric center point V₀ on a geographical distribution of K number of spectrum monitoring stations in an area is obtained by the following step:

$${V}_{0} = \frac{1}{K} {\sum }_{i = 1}^{K} {V}_{i}$$

where n takes the value 1, 2, 3, . . . , K; Vᵢ refers to the latitude and longitude positions of the i-th number station.

Furthermore, a distance Dₙ between the latitude and longitude position Vₙ of each spectrum monitoring station and the geometric center point V₀ is obtained by the following step:

Dₙ=∥Vₙ−V₀∥₂

where ∥·∥₂ is the second-order norm operation.

Furthermore, the three-dimensional frequency spectrum matrix body Q is formed by the following steps:

according to the order from small to large of the distance Dₙ between the spectrum monitoring station and the geometric center point V₀, arrange the corresponding spectrum matrix of the station to construct the three-dimensional spectrum matrix body Q=[W₁, W₂, W_{K}]^{T}, the spectrum matrix body Q is in N×M×K dimension, W₁, W₂, . . . W_{K} refers to the two-dimensional spectrum matrix of K stations in an area within a given time period.

Furthermore, when the total of the spectrum monitoring data of the stations in a multiple area is required to be obtained, the three-dimensional spectrum matrix of the stations in each area is processed as follows:

Qᵢ+Qⱼ=[W₁ⁱ+W₁^{j},W₂ⁱ+W₂^{j}, . . . W_{K}ⁱ+W_{K}^{j}]^{T}

When the difference of the spectrum monitoring data of stations in two area is required to be obtained, the three-dimensional spectrum matrix of the stations in two area is processed as follows:

Qᵢ−Qⱼ=[W₁ⁱ−W₁^{j},W₂ⁱ−W₂^{j}, . . . W_{K}ⁱ−W_{K}^{j}]^{T}

When the spectrum evaluation usage of the spectrum monitoring data of a station in a certain frequency band is required, the two-dimensional spectrum matrix of the stations in the area is processed as follows:

TProj(Q)=[TProj(W₁),TProj(W₂), . . . TProj(W_{K})]^{T}

When the spectrum evaluation usage of the spectrum monitoring data of the stations of the area in a certain frequency band is required, the three-dimensional spectrum matrix of the stations in the area is processed as follows:

FProj(Q)=[FProj(W₁),FProj(W₂), . . . FProj(W_{K})]^{T}

When the multiplication data of the spectrum monitoring data of the stations of the area in a certain frequency band is required, the three-dimensional spectrum matrix of the stations in the area is processed as follows:

mQ=[mW₁,mW₂, . . . mW_{K}]¹.

where Qᵢ and Qⱼ are the three-dimensional spectrum matrix of stations in an area, both are N×M×K dimensions, Qᵢ=[W₁ⁱ, W₂ⁱ, . . . W_{K}ⁱ]^{T}, =[W₁^{j}, W₂^{j}, . . . W_{K}^{j}]^{T}.

On the other hand, the present invention provides a compression processing method for spectrum monitoring data of multiple stations, which comprises:

S1: arrange the two-dimensional spectrum matrices of multiple stations to form a three-dimensional spectrum matrix body according to the mutual relationship between the positions of the stations, wherein the two-dimensional spectrum matrix of each station is formed by the discretization of the spectrum monitoring data of the station in the time and frequency dimensions;

S2: Select one dimension from the three dimensions of the three-dimensional frequency spectrum matrix body, carrying out grayscale processing of each matrix to convert to grayscale image;

S3: compress the spectrum monitoring data in the selected dimension by using video compression method.

Furthermore, in the step S1, the two-dimensional matrix is arranged as follows:

Select a station as a reference station, and arrange the spectrum matrix data corresponding to each station based on a standard of geographic straight-line distance between all stations and the reference point; or

Select a geographic position corresponding to the average longitude and latitude of geographic locations of multiple stations in a certain area as a reference point, and arrange the spectrum matrix data corresponding to each station based on a standard of geographic straight-line distance between all stations and the reference point; or

Select a random geographic position as a reference point, and arrange the spectrum matrix data corresponding to each station based on a standard of a geographic straight-line distance between all stations and the reference point.

Furthermore, in the step S2, the steps of gray-scale processing of the spectrum monitoring data is selected from one of the following three method:

select the time dimension as the reference dimension and carry out grayscale processing on each matrix to convert each matrix into a grayscale image; or

select the frequency dimension as the reference dimension and carry out grayscale processing on each matrix to convert each matrix into a grayscale image; or

select the position dimension as the reference dimension and carry out grayscale processing on each matrix to convert each matrix into a grayscale image.

Compared to conventional technologies, the present invention fully excavates the data correlation and redundancy of the spectrum monitoring data of multiple stations in the time, frequency, and position dimensions, and realizes the compression processing of the structured spectrum monitoring data by using the video compression method.

### BRIEF DESCRIPTION OF THE DRAWINGS

FIG. 1 is a schematic diagram of application scenarios of a method for structured representation of spectrum monitoring data according to the present invention.

FIG. 2 is schematic diagram of spectrum matrix of a method for structured representation of spectrum monitoring data according to the present invention

FIG. 3 illustrates an example of the grayscale image of the spectrum matrix of the spectrum monitoring data.

FIG. 4 is a flow chart of a compression processing method for spectrum monitoring data of multiple stations according to the present invention.

FIG. 5 is a schematic diagram of application scenarios of the compression processing method for spectrum monitoring data of multiple stations according to the present invention.

FIG. 6 is a schematic diagram of using time dimension as the reference dimension to carry out gray-scale processing of spectrum matrix body according to the present invention.

FIG. 7 is a schematic diagram of using frequency dimension as the reference dimension to carry out gray-scale processing of spectrum matrix body according to the present invention.

FIG. 8 is a schematic diagram of using position dimension as the reference dimension to carry out gray-scale processing of spectrum matrix body according to the present invention.

### DETAILED DESCRIPTION OF THE PREFERRED EMBODIMENT

The implementations of the present invention are further described in details with the accompanying drawings and embodiments in the followings.

In order to make the objectives, technical solutions and advantages of the embodiments of the present invention clearer, the technical solutions in the embodiments of the present invention will be described clearly and completely in conjunction with the accompanying drawings in the embodiments of the present invention. Obviously, the described embodiments are only some of the embodiments of the present invention, rather than all the embodiments. The components of the embodiments of the present invention generally described and shown in the drawings herein may be arranged and designed in various different configurations. Therefore, the following detailed description of the embodiments of the present invention provided in the accompanying drawings is not intended to limit the scope of the claimed invention, but merely represents the preferred embodiments of the present invention. Based on the embodiments of the present invention, all other embodiments obtained by those skilled in the art without inventive work shall fall within the protection scope of the present invention.

The present invention mainly applies the compression and transmission of spectrum monitoring data of multiple stations, which is beneficial to the more reasonable and efficient utilization of monitoring data of multiple stations.

The First Aspect

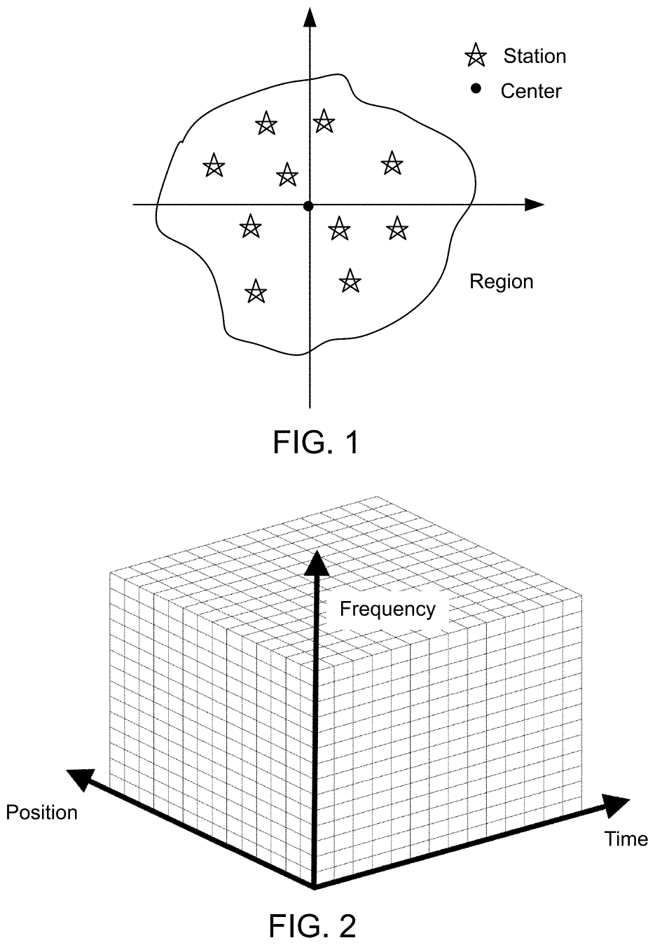

FIG. 1 is a schematic diagram of application scenarios of a method for structured representation of spectrum monitoring data according to an embodiment of the present invention. The present invention provides a structured representation method for spectrum monitoring data, which comprises the following implementation steps:

1) discretizing spectrum monitoring data of a single station in time dimension and frequency dimension to form a two-dimensional spectrum matrix;

2) constructing a three-dimensional spectrum matrix by using the two-dimensional spectrum matrix obtained from all stations in a certain area, taking a certain point as a center, and aligning in a position dimension according to certain rules.

In the above structured representation method of spectrum monitoring data, the two-dimensional spectrum matrix is constructed by the following steps of:

Step 1: S1.1: the spectrum monitoring station, according to a synchronization or calibration method, obtaining a synchronized clock with other stations, then obtaining information such as a uniformly specified sampling time tₙ(1 . . . N), spectrum bandwidth B and frequency sampling points M;

Step 2: at the sampling time tₙ, using information of the spectrum bandwidth B and the number of frequency sampling points M to discretize the monitoring data in the frequency dimension to obtain a vector Iₜ_{ₙ}, and a sequence Iₜ_{ₙ} is 1×M dimension;

Step 3: for a given monitoring time period, at the sampling time tₙ, obtaining spectrum monitoring vectors at different sampling time Iₜ_{₁}, Iₜ_{₂}, . . . , Iₜ_{_{N}};

Step 4: aligning the spectrum monitoring vectors at different sampling time in chronological order to form a two-dimensional spectrum matrix W=[Iₜ_{₁} Iₜ_{₂} . . . Iₜ_{_{N}}]^{T}, the matrix W is N×M dimension.

In the structured representation method of spectrum monitoring data, the three-dimensional spectrum matrix body is constructed by the following steps:

Step 1: obtaining the monitoring data of all K number of spectrum monitoring stations in a certain area within a given time period, which are W₁, W₂, . . . W_{K};

Step 2: according to the interrelation between the positions of the K number of spectrum monitoring stations, arrange W₁, W₂, . . . W_{K} to form a three-dimensional spectrum matrix body Q=[W₁, W₂, . . . W_{K}]^{T}, the matrix body Q is N×M×K dimension.

In the structured representation method of spectrum monitoring data, the two-dimensional spectrum matrix defines the following mathematical operations:

(1) assume the two-dimensional spectrum matrix is Wᵢ, both of which are N×M dimension, then

Spectrum Matrix Addition:

$${W}_{i} + {W}_{j} = ( \begin{matrix}{x}_{11} & … & {x}_{1 N} \\ ⋮ & ⋱ & ⋮ \\ {x}_{M 1} & … & {x}_{NM}\end{matrix} ) + ( \begin{matrix}{y}_{11} & … & {y}_{1 N} \\ ⋮ & ⋱ & ⋮ \\ {y}_{M 1} & … & {y}_{NM}\end{matrix} ) = ( \begin{matrix}{x}_{11} + {y}_{11} & … & {x}_{1 N} + {y}_{1 N} \\ ⋮ & ⋱ & ⋮ \\ {x}_{M 1} + {y}_{M 1} & … & {x}_{NM} + {y}_{NM}\end{matrix} )$$

The spectrum matrix addition can be applied to obtain the sum of the spectrum data of multiple stations so as to obtain the overall average data of the spectrum usage condition in a certain area.

Spectrum Matrix Subtraction:

$${W}_{i} - {W}_{j} = ( \begin{matrix}{x}_{11} & … & {x}_{1 N} \\ ⋮ & ⋱ & ⋮ \\ {x}_{M 1} & … & {x}_{NM}\end{matrix} ) - ( \begin{matrix}{y}_{11} & … & {y}_{1 N} \\ ⋮ & ⋱ & ⋮ \\ {y}_{M 1} & … & {y}_{NM}\end{matrix} ) = ( \begin{matrix}{x}_{11} - {y}_{11} & … & {x}_{1 N} - {y}_{1 N} \\ ⋮ & ⋱ & ⋮ \\ {x}_{M 1} - {y}_{M 1} & … & {x}_{NM} - {y}_{NM}\end{matrix} )$$

The spectrum matrix subtraction can be used to process subtraction between the spectrum data of multiple stations so as to obtain information on the difference in the spectrum usage condition between different stations; it can also be used to subtract the station monitoring data from the electromagnetic background data to obtain the monitoring data of a specific emitter.

(2) Frequency dimension projection of spectrum matrix:

$$FProj ( W ) = ( \begin{matrix}{\sum }_{i = 1}^{N} {x}_{1 i} \\ {\sum }_{i = 1}^{N} {x}_{2 i} \\ ⋮ \\ {\sum }_{i = 1}^{N} {x}_{Mi}\end{matrix} ) = ( \begin{matrix}{Z}_{1} \\ {Z}_{2} \\ ⋮ \\ {Z}_{M}\end{matrix} )$$

The frequency dimension projection of the spectrum matrix can obtain the average spectrum usage condition of a single station in a certain period of time.

(3) Time dimension projection of spectrum matrix:

$$TProj ( W ) = ( \begin{matrix}{\sum }_{i = 1}^{M} {x}_{i 1} & {\sum }_{i = 1}^{M} {x}_{i 2} & … & {\sum }_{i = 1}^{M} {x}_{i N}\end{matrix} ) = ( \begin{matrix}{L}_{1} & {L}_{2} & … & {L}_{N}\end{matrix} )$$

The frequency dimension projection of the spectrum matrix can obtain the time occupancy of a single station in a given spectrum segment.

(4) m is a Real Number, then Multiply the Spectrum Matrix Number:

$$mW = ( \begin{matrix}{mx}_{11} & … & {mx}_{1 N} \\ ⋮ & ⋱ & ⋮ \\ {mx}_{M 1} & … & {mx}_{NM}\end{matrix} )$$

In the structured representation method of spectrum monitoring data, the three-dimensional frequency spectrum matrix body defines the following mathematical operations:

(1) Assuming that the spectrum matrices are Qᵢ and Qᵢ, both of which are N×M×K dimensions, then

Spectrum Matrix Addition:

Qᵢ+Qⱼ=[W₁ⁱ,W₂ⁱ, . . . W_{K}ⁱ]^{T}+[W₁^{j},W₂^{j}, . . . W_{K}^{j}]^{T}=[W₁ⁱ+W₁^{j},W₂ⁱ+W₂^{j}, . . . W_{K}ⁱ+W_{K}^{j}]^{T}

The spectrum matrix addition can be applied to obtain the sum of the spectrum data of multiple stations so as to obtain the overall average data of the spectrum usage condition in a larger area.

Spectrum Matrix Subtraction:

Qᵢ−Qⱼ=[W₁ⁱ,W₂ⁱ, . . . W_{K}ⁱ]^{T}−[W₁^{j},W₂^{j}, . . . W_{K}^{j}]^{T}=[W₁ⁱ−W₁^{j},W₂ⁱ−W₂^{j}, . . . W_{K}ⁱ−W_{K}^{j}]^{T}

The spectrum matrix subtraction can be used to process subtraction between the spectrum data of multiple stations so as to obtain information on the difference in the spectrum usage condition between different areas; it can also be used to subtract the area monitoring data from the area electromagnetic background data to obtain the monitoring data of a specific emitter of a specific area.

(2) Projection of Frequency Dimension of Spectrum Matrix:

FProj(Q)=[FProj(W₁),FProj(W₂),FProj(W_{K})]^{T}

The projection of frequency dimension of the spectrum matrix can obtain a relationship between the spectrum usage condition and the geolocation of an area in a certain period of time.

(3) The projection of time dimension of the spectrum matrix

TProj(Q)=[TProj(W₁),TProj(W₂),TProj(W_{K})]^{T}

The projection of time dimension of the spectrum matrix can obtain a relationship between the spectrum usage time and the geolocation of an area in a certain period of time.

(4) m is a Real Number, then Multiplication Operation of the Spectrum Matrix Body is:

mQ=[mW₁,mW₂, . . . mW_{K}]^{T}

In the step of constructing the three-dimensional spectrum matrix body, the spectrum matrix body formed by the spectrum matrix W₁, W₂, . . . W_{K} of the K number of spectrum monitoring stations can employ the following steps and rules:

Step 1: Calculate a geometric center point V₀ on a geographical distribution according to latitude and longitude positions Vₙ (1 . . . K) of K number of spectrum monitoring stations;

$${V}_{0} = \frac{1}{K} {\sum }_{i = 1}^{K} {V}_{i}$$

Step 2: Calculate the distance Dₙ between the latitude and longitude position Vₙ of each spectrum monitoring station and the geometric center point V₀, where ∥·∥₂ is the second-order norm operation:

Dₙ=∥Vₙ−V₀∥₂

Step 3: According to the order from small to large of the distance Dₙ between the spectrum monitoring station and the geometric center point V₀, arrange the corresponding spectrum matrix of the station to construct the spectrum matrix body Q=[W₁, W₂, . . . W_{K}]^{T}.

For the monitoring data of a single station, the present invention expresses it in the form of a spectrum matrix. The advantages are as follows: First, it is beneficial to use the structured representation and calculation method of the traditional frequency spectrum matrix to carry out subsequent data processing; second, the information in the two dimensions of time and frequency of spectrum data is associated at the bottom level, which is similar to waterfall chart and time-frequency chart, so it is helpful for further information mining; finally, the spectrum matrix representation of the spectrum monitoring data can map the spectrum data to a grayscale image, and can use the image compression method for compression processing and transmission. For example, the use of spectrum matrix representation can assist in completing the following tasks:

(1) The changes in spectrum usage over time at the station location;

(2) Using matrix addition and number multiplication to complete the spectrum usage statistics at the station location;

(3) Achieve unified spectrum data format and compressed transmission.

For multiple stations spectrum monitoring data, the present invention provides the concept of a spectrum matrix body and a structured representation method, which has the following advantages: first, this method extends the traditional matrix form to a new dimension to identify the position dimension of the spectrum monitoring data, so as to realize the correlation of the four dimensions of time, spectrum, space and energy of the spectrum data to form an organization system that conforms to the structured spectrum monitoring data; second, the present invention further defines mathematical operations for the spectrum matrix body, thereby facilitating the processing of information mining on massive monitoring data; (3) the spectrum matrix body can convert the spectrum data of multiple stations in a certain area into video data for compression and transmission. For example, the use of spectrum matrix expression and operation can assist in completing the following tasks:

(1) Statistically calculate the changes in spectrum usage over time in a given area;

(2) Statistically calculate the changes in spectrum usage with space in a given time;

(3) Statistically calculate the usage of a given spectrum in a certain time and space;

(4) Realize unification of spectrum data format and compressed transmission;

(5) Realize self-positioning and tracking of emitters;

(6) Realize the stability analysis of the radiation intensity of a certain emitter;

(7) Calculate of the complexity of the space electromagnetic environment within a certain frequency band and time period.

In addition, the structured representation method of spectrum monitoring data proposed by the present invention is more suitable for the requirements of construction of spectrum monitoring station network and big data processing, so that the spectrum monitoring data can be used more reasonably and efficiently.

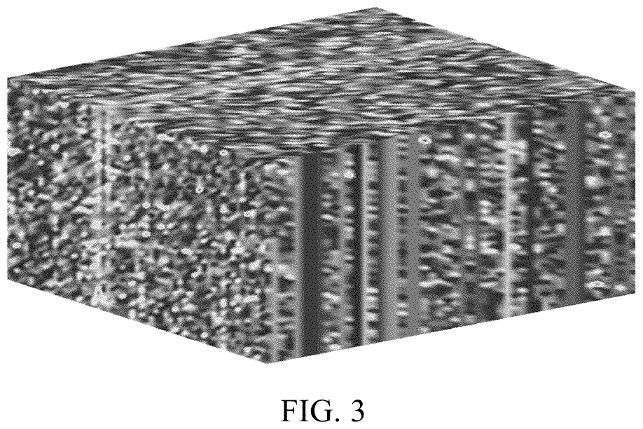

FIG. 3 shows an example of spectrum monitoring data obtained at 55 points in a place in Lintong using a spectrum analyzer expressed as a spectrum matrix body. 50 sampling moments are taken in the time domain, the sampling bandwidth is 500 MHz, the number of sampling points in the frequency domain is 501, and the spectral moment matrix Q is 50×501×55 dimensions. The figure shows the grayscale map of the spectrum matrix obtained by mapping 55 spectrum matrices into 8-level grayscale which are composed into a spectrum matrix body.

The Second Aspect

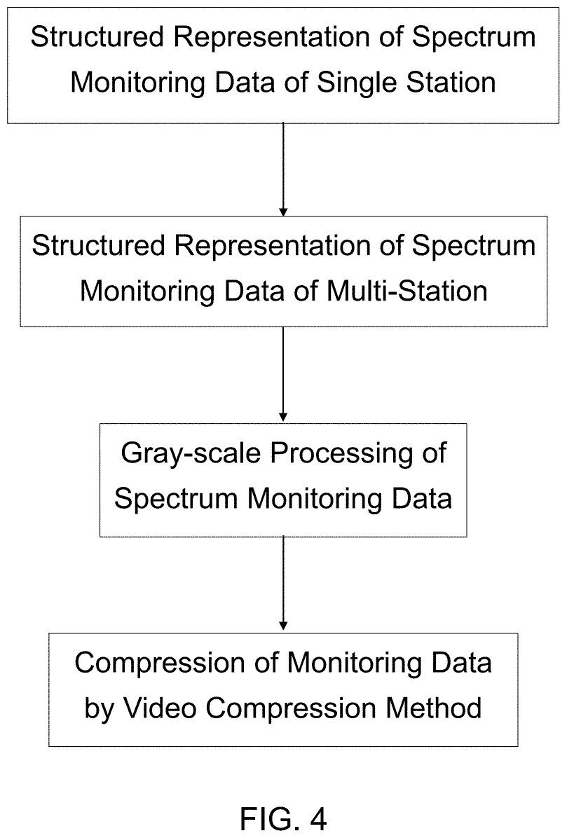

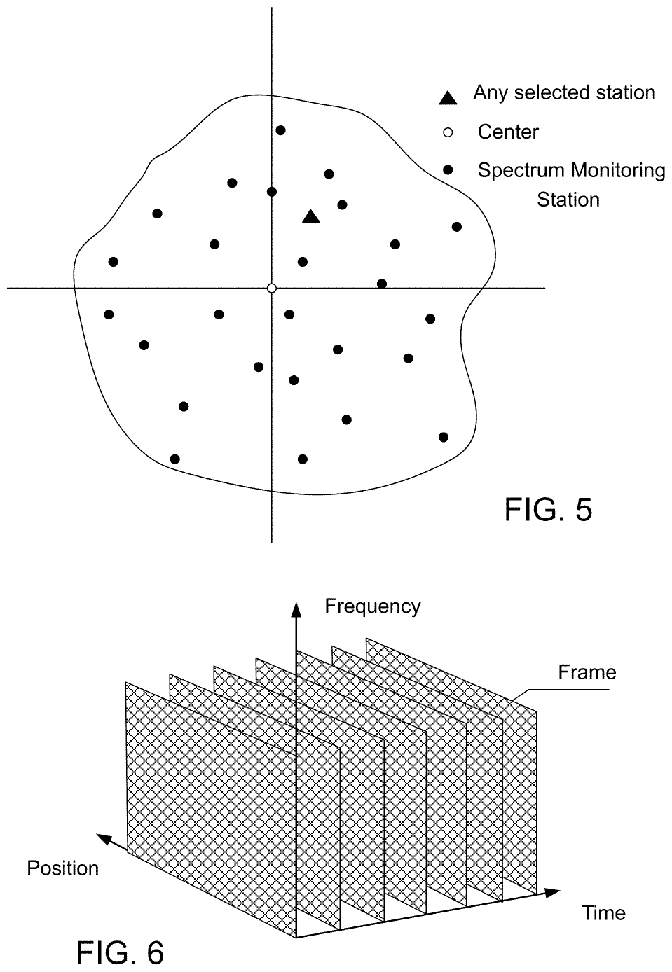

FIG. 4 is a flow chart of a compression processing method for spectrum monitoring data of multiple stations according to the present invention. FIG. 5 is a schematic diagram of application scenarios of the compression processing method for spectrum monitoring data of multiple stations according to an embodiment of the present invention.

Referring to FIG. 5, a compression processing method for spectrum monitoring data of multiple stations comprises the following steps:

Structured representation of spectrum monitoring data of single station: according to a unified monitoring frequency bandwidth, monitoring a sampling interval of time dimension and a sampling interval of frequency dimension, completing discretization of the frequency dimension and discretization of the time dimension of the monitoring data in a given time period at a given time and a given bandwidth, expressing the spectrum monitoring data of the given monitoring time period and the frequency bandwidth as a spectrum matrix;

Structured representation of spectrum monitoring data of multiple stations: arranging all the spectrum matrices obtained by the multiple stations in a given area into a spectrum matrix body according to specific rules of the station position.

The two-dimensional spectrum matrix is constructed by the following steps of:

Step 1: the spectrum monitoring station, according to a synchronization or calibration method, obtaining a synchronized clock with other stations, then obtaining information such as a uniformly specified sampling time tₙ (1 . . . N), spectrum bandwidth B and frequency sampling points M;

Step 2: at the sampling time tₙ, using information of the spectrum bandwidth B and the number of frequency sampling points M to discretize the monitoring data in the frequency dimension to obtain a vector Iₜ_{ₙ}, and a sequence Iₜ_{ₙ} is 1×M dimension;

Step 3: for a given monitoring time period, at the sampling time tₙ(1 . . . N), obtaining spectrum monitoring vectors at different sampling time Iₜ_{₁}, Iₜ_{₂}, . . . , Iₜ_{_{N}};

Step 4: aligning the spectrum monitoring vectors at different sampling time in chronological order to form a two-dimensional spectrum matrix W=[Iₜ_{₁}Iₜ_{₂} . . . Iₜ_{_{N}}]^{T}, the matrix W is N×M dimension.

In the structured representation method of spectrum monitoring data, the three-dimensional spectrum matrix body can be constructed by the following steps:

Step 1: obtaining the monitoring data of all K number of spectrum monitoring stations in a certain area within a given time period, which are W₁, W₂, . . . W_{K};

Step 2: according to the interrelation between the positions of the K number of spectrum monitoring stations, arrange W₁, W₂, . . . W_{K} to form a three-dimensional spectrum matrix body Q=[W₁, W₂, . . . W_{K}]^{T}, the matrix body Q is N×M×K dimension.

Gray-scale processing of spectrum monitoring data: select a dimension from the three dimensions of the spectrum matrix body, where the spectrum matrix body can be regarded as the arrangement of a series of matrices in this dimension, and transform each matrix into a grayscale image by gray-scale processing, and the spectrum matrix body can be regarded as a piece of video data;

Use of video compression method to compress the monitoring data: for the monitoring data of multiple stations in a given area, there is a large amount of redundant information in the dimensions of time, frequency, and position. Traditional video compression standards can be used to compress the video data corresponding to the spectrum matrix. The usual video compression standards are H.264, H.265, MPEG4, MJPEG, etc. H.264 has a high compression ratio and also ensures high-quality and smooth images. H.265 is more suitable for HD/UHD transmission. The specific compression method and standard can be selected according to actual needs.

In the step of structured representation of multi-station spectrum monitoring data of the compression processing method for spectrum monitoring data of multiple stations, the following two methods can be used to arrange the spectrum matrix into a spectrum matrix body:

Select a monitoring station as a reference station, and arrange the spectrum matrix data corresponding to each station based on a geographic straight-line distance between all stations and the reference station, the position dimension is scaled with the geographic straight-line distance between the station and the reference station;

Select a geographic position corresponding to the average longitude and latitude of geographic locations of multiple stations in a certain area as a reference point, and arrange the spectrum matrix data corresponding to each station based on a geographic straight-line distance between all stations and the reference point.

In the steps of the gray-scale processing of the spectrum monitoring data of the compression processing method for spectrum monitoring data of multiple stations, the spectrum monitoring data can use the following three methods for gray-scale processing:

Referring to FIG. 6, select the time dimension as the reference dimension such that the spectrum matrix body can be regarded as data arranged by a series of two-dimensional matrices corresponding to each time point; carry out grayscale processing on each matrix to convert each matrix into a grayscale image such that in the time dimension, the spectrum matrix body can be regarded as a piece of video data.

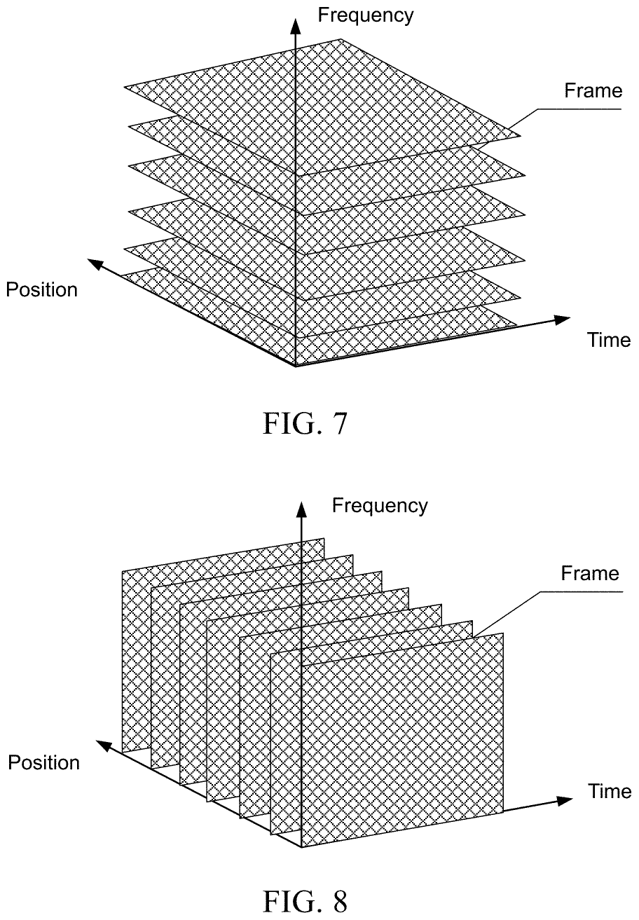

Referring to FIG. 7, select the frequency dimension as the reference dimension such that the spectrum matrix body can be regarded as data arranged by a series of two-dimensional matrices corresponding to each time point; carry out grayscale processing on each matrix to convert each matrix into a grayscale image such that in the frequency dimension, the spectrum matrix body can be regarded as a piece of video data.

Referring to FIG. 8, select the position dimension as the reference dimension such that the spectrum matrix body can be regarded as data arranged by a series of two-dimensional matrices corresponding to each time point; carrying out grayscale processing on each matrix to convert each matrix into a grayscale image such that in the position dimension, the spectrum matrix body can be regarded as a piece of video data.

The steps to processing grayscale of a two-dimensional matrix are:

Get the maximum and minimum values of a two-dimensional matrix, mapping a two-dimensional matrix to a certain number of grayscale images.

What is claimed is:

1. A structured representation method of spectrum monitoring data, characterized in that, comprising the following steps of:
S1: discretizing spectrum monitoring data of a single station in time dimension and frequency dimension to form a two-dimensional spectrum matrix;
S2: constructing a three-dimensional spectrum matrix by using the two-dimensional spectrum matrix obtained from all stations in a certain area, taking a certain point as a center, and aligning in a position dimension according to certain rules.

2. The structured representation method of spectrum monitoring data according to claim 1, characterized in that, in the step S1, the two-dimensional spectrum matrix is formed by the following steps of:
S1.1: the spectrum monitoring station, according to a synchronization or calibration method, obtaining a synchronized clock with other stations, then obtaining a uniformly specified sampling time tₙ, spectrum bandwidth B and frequency sampling points M, where n is 1, 2, 3, . . . , N, N is a positive integer;
S1.2: at the sampling time tₙ, using the spectrum bandwidth B and the number of frequency sampling points M to discretize the monitoring data in the frequency dimension to obtain a vector Iₜ_{ₙ}, and a sequence Iₜ_{ₙ} is 1×M dimension;
S1.3: for a given monitoring time period, at the sampling time tₙ, obtaining spectrum monitoring vectors at different sampling time Iₜ_{₁}, Iₜ_{₂}, . . . , Iₜ_{_{N}};
S1.4: aligning the spectrum monitoring vectors at different sampling time in chronological order to form a two-dimensional spectrum matrix W=[Iₜ_{₁} Iₜ_{₂} . . . Iₜ_{_{N}}]^{T}, the matrix W is N×M dimension.

3. The structured representation method of spectrum monitoring data according to claim 2, characterized in that, in the step S1, the two-dimensional spectrum matrix defines the following mathematical operations:
assume the two-dimensional frequency spectrum matrix is Wᵢ, Wⱼ, both of which are N×M dimension,
$${W}_{i} = ( \begin{matrix}{x}_{11} & … & {x}_{1 N} \\ ⋮ & ⋱ & ⋮ \\ {x}_{M 1} & … & {x}_{NM}\end{matrix} ) , {W}_{j} = ( \begin{matrix}{y}_{11} & … & {y}_{1 N} \\ ⋮ & ⋱ & ⋮ \\ {y}_{M 1} & … & {y}_{NM}\end{matrix} ) ,$$
then
Spectrum matrix addition:
$${W}_{i} + {W}_{j} = ( \begin{matrix}{x}_{11} + {y}_{11} & … & {x}_{1 N} + {y}_{1 N} \\ ⋮ & ⋱ & ⋮ \\ {x}_{M 1} + {y}_{M 1} & … & {x}_{NM} + {y}_{NM}\end{matrix} )$$
Spectrum matrix subtraction:
$${W}_{i} - {W}_{j} = ( \begin{matrix}{x}_{11} - {y}_{11} & … & {x}_{1 N} - {y}_{1 N} \\ ⋮ & ⋱ & ⋮ \\ {x}_{M 1} - {y}_{M 1} & … & {x}_{NM} - {y}_{NM}\end{matrix} )$$
Frequency dimension projection of spectrum matrix:
$$FProj ( W ) = ( \begin{matrix}{\sum }_{i = 1}^{N} {x}_{1 i} \\ {\sum }_{i = 1}^{N} {x}_{2 i} \\ ⋮ \\ {\sum }_{i = 1}^{N} {x}_{M i}\end{matrix} ) = ( \begin{matrix}{Z}_{1} \\ {Z}_{2} \\ ⋮ \\ {Z}_{M}\end{matrix} )$$
Time dimension projection of spectrum matrix:
$$TProj ( W ) = ( \begin{matrix}{\sum }_{i = 1}^{M} {x}_{i 1} & {\sum }_{i = 1}^{M} {x}_{i 2} & … & {\sum }_{i = 1}^{M} {x}_{i N}\end{matrix} ) = ( \begin{matrix}{L}_{1} & {L}_{2} & … & {L}_{N}\end{matrix} )$$
m is a real number, then multiply the spectrum matrix number:
$$m W = ( \begin{matrix}m {x}_{11} & … & m {x}_{1 N} \\ ⋮ & ⋱ & ⋮ \\ m {x}_{M 1} & … & m {x}_{N M}\end{matrix} )$$

4. The structured representation method of spectrum monitoring data according to claim 1, characterized in that, in the step S2, the three-dimensional spectrum matrix is constructed by the following steps:
S2.1: obtaining the monitoring data of all K spectrum monitoring stations in a certain area within a given time period, which are W₁, W₂, . . . W_{K};
S2.2: According to the relationship between the positions of the K number of spectrum monitoring stations, arrange W₁, W₂, . . . W_{K} to form a three-dimensional spectrum matrix body Q=[W₁, W₂, . . . W_{K}]^{T}, the matrix body Q is N×M×K dimension.

5. The structured representation method of spectrum monitoring data according to claim 1, characterized in that, in the step S2.2, the spectrum matrix body Q formed by the spectrum matrix W₁, W₂, . . . W_{K} of the K number of spectrum monitoring stations employs the following steps and rules:
S2.2.1: Calculate a geometric center point V₀ on a geographical distribution according to latitude and longitude positions Vₙ of K number of spectrum monitoring stations, where n takes the value 1, 2, 3, . . . , K;
$${V}_{0} = \frac{1}{K} {\sum }_{i = 1}^{K} {V}_{i}$$
S2.2.2: Calculate the di stance Dₙ between the latitude and longitude position Vₙ of each spectrum monitoring station and the geometric center point V₀, where ∥·∥₂ is the second-order norm operation:
Dₙ=∥Vₙ−V₀∥₂
S2.2.3: according to the order from small to large of the distance Dₙ between the spectrum monitoring station and the geometric center point V₀, arrange the corresponding spectrum matrix of the station to construct the spectrum matrix body Q=[W₁, W₂, . . . W_{K}]^{T}.

6. The structured representation method of spectrum monitoring data according to claim 4, characterized in that, in the step S2, the three-dimensional frequency spectrum matrix defines the following mathematical operations:
Assuming that the spectrum moments are Qᵢ and Qⱼ, both of which are N×M×K dimensions, Qᵢ=[W₁ⁱ, W₂ⁱ, . . . W_{K}ⁱ]^{T}, Qⱼ=[W₁^{j}, W₂^{j}, . . . W_{K}^{j}]^{T}, then
Spectrum matrix addition:
Qᵢ+Qⱼ=[W₁ⁱ+W₁^{j},W₂ⁱ+W₂^{j}, . . . W_{K}ⁱ+W_{K}^{j}]^{T}
Spectrum matrix subtraction:
Qᵢ−Qⱼ;=[W₁ⁱ−W₁^{j},W₂ⁱ−W₂^{j}, . . . W_{K}ⁱ−W_{K}^{j}]^{T}
Frequency dimension projection of spectrum matrix:
FProj(Q)=[FProj(W₁),FProj(W₂), . . . FProj(W_{K})]^{T}
Time dimension projection of spectrum matrix:
TProj(Q)=[TProj(W₁),TProj(W₂), . . . TProj(W_{K})]^{T}
m is a real number, then multiply the spectrum matrix number:
mQ=[mW₁,mW₂, . . . mW_{K}]T.

7. A compression processing method for spectrum monitoring data of multiple stations, characterized in that, comprising the following steps of:
S1: structured representation of spectrum monitoring data of single station: according to a unified monitoring frequency bandwidth, monitoring a sampling interval of time dimension and a sampling interval of frequency dimension, completing discretization of the frequency dimension and discretization of the time dimension of the monitoring data in a given time period at a given time and a given bandwidth, expressing the spectrum monitoring data of the given monitoring time period and the frequency bandwidth as a spectrum matrix;
S2: structured representation of spectrum monitoring data of multiple stations: arranging all the spectrum matrices obtained by the multiple stations in a given area into a spectrum matrix body according to specific rules of the station position;
S3: Gray-scale processing of spectrum monitoring data: selecting a dimension from the three dimensions of the spectrum matrix body, where the spectrum matrix body can be regarded as an arrangement of a series of matrices in the selected dimension, transforming each of the matrices into a grayscale image by gray-scale processing such that the spectrum matrix body can be regarded as a piece of video data;
S4: Utilization of video compression method to compress monitoring data: for the monitoring data of multiple stations in a given area, there is a large amount of redundant information in the dimensions of time, frequency, and position, compressing the video data corresponding to the spectrum matrix body by using traditional video compression standards.

8. The compression processing method for spectrum monitoring data of multiple stations according to claim 1, in the step S2, rules for arranging the spectrum matrices into the spectrum matrix body adopt one of the following three methods:
Selecting a monitoring station as a reference station, and arranging the spectrum matrix data corresponding to each station based on a geographic straight-line distance between all stations and the reference point; or
Selecting a geographic position corresponding to the average longitude and latitude of geographic locations of multiple stations in a certain area as a reference point, and arranging the spectrum matrix data corresponding to each station based on a geographic straight-line distance between all stations and the reference point; or
Selecting one particular geographic position as a reference point, and arranging the spectrum matrix data corresponding to each station based on a geographic straight-line distance between all stations and the reference point.

9. The compression processing method for spectrum monitoring data of multiple stations according to claim 1, in the step S3, for the steps of the gray-scale processing of the spectrum monitoring data, selecting one of the following three methods:
selecting the time dimension as the reference dimension such that the spectrum matrix body can be regarded as data arranged by a series of two-dimensional matrices corresponding to each time point; carrying out grayscale processing on each matrix to convert each matrix into a grayscale image such that in the time dimension, the spectrum matrix body can be regarded as a piece of video data; or
selecting the frequency dimension as the reference dimension such that the spectrum matrix body can be regarded as data arranged by a series of two-dimensional matrices corresponding to each time point; carrying out grayscale processing on each matrix to convert each matrix into a grayscale image such that in the time dimension, the spectrum matrix body can be regarded as a piece of video data; or
selecting the position dimension as the reference dimension such that the spectrum matrix body can be regarded as data arranged by a series of two-dimensional matrices corresponding to each time point; carrying out grayscale processing on each matrix to convert each matrix into a grayscale image such that in the time dimension, the spectrum matrix body can be regarded as a piece of video data.

10. A processing method of spectrum monitoring data, characterized in that, comprising:
Arrange the two-dimensional spectrum matrices of multiple stations to form a three-dimensional spectrum matrix body according to inter-relationship between positions of the multiple stations,
wherein the two-dimensional spectrum matrix of each station is formed by the discretization of spectrum monitoring data of the station in time and frequency dimensions.

11. A processing method of spectrum monitoring data according to claim 10, characterized in that, the two-dimensional spectrum matrix of each station is formed by the following steps:
S1.1: obtaining a synchronized clock of one station with other stations, then obtaining a uniformly specified sampling time tₙ (1 . . . N), spectrum bandwidth B and frequency sampling points M;
S1.2: at the sampling time tₙ, using the spectrum bandwidth B and the frequency sampling points M to discretize the monitoring data in the frequency dimension to obtain a vector Iₜ_{ₙ}, and a sequence Iₜ_{ₙ} is 1×M dimension;
S1.3: for a given monitoring time period, at the sampling time tₙ, obtaining spectrum monitoring vectors at different sampling time Iₜ_{₁}, Iₜ_{₂}, . . . , Iₜ_{_{N}};
S1.4: aligning the spectrum monitoring vectors at different sampling time in chronological order to form a two-dimensional spectrum matrix W=[Iₜ_{₁} Iₜ_{₂} . . . Iₜ_{_{N}}]^{T}, the matrix W is N×M dimension.

12. The processing method of spectrum monitoring data according to claim 11, characterized in that,
when the sum of the spectrum monitoring data of a station is required to be obtained, the two-dimensional spectrum matrix of the multiple stations is processed as follows:
$${W}_{i} + {W}_{j} = ( \begin{matrix}{x}_{11} + {y}_{11} & … & {x}_{1 N} + {y}_{1 N} \\ ⋮ & ⋱ & ⋮ \\ {x}_{M 1} + {y}_{M 1} & … & {x}_{NM} + {y}_{NM}\end{matrix} )$$
when the difference of the spectrum monitoring data of a station is required to be obtained, the two-dimensional spectrum matrix of the multiple stations is processed as follows:
$${W}_{i} + {W}_{j} = ( \begin{matrix}{x}_{11} - {y}_{11} & … & {x}_{1 N} - {y}_{1 N} \\ ⋮ & ⋱ & ⋮ \\ {x}_{M 1} - {y}_{M 1} & … & {x}_{NM} - {y}_{NM}\end{matrix} )$$
$$wherein , \\ {W}_{i} = ( \begin{matrix}{x}_{11} & … & {x}_{1 N} \\ ⋮ & ⋱ & ⋮ \\ {x}_{M 1} & … & {x}_{NM}\end{matrix} ) , {W}_{j} = ( \begin{matrix}{y}_{11} & … & {y}_{1 N} \\ ⋮ & ⋱ & ⋮ \\ {y}_{M 1} & … & {y}_{NM}\end{matrix} ) ,$$
when the usage condition of the spectrum monitoring data of a station in a certain period of time is required, the two-dimensional spectrum matrix of the station is processed as follows:
$$TProj ( W ) = ( \begin{matrix}{\sum }_{i = 1}^{M} {x}_{i 1} & {\sum }_{i = 1}^{M} {x}_{i 2} & … & {\sum }_{i = 1}^{M} {x}_{i N}\end{matrix} ) = ( \begin{matrix}{L}_{1} & {L}_{2} & … & {L}_{N}\end{matrix} )$$
when the spectrum evaluation usage of the spectrum monitoring data of a station in a certain frequency band is required, the two-dimensional spectrum matrix of the station is processed as follows:
$$FProj ( W ) = ( \begin{matrix}{\sum }_{i = 1}^{N} {x}_{1 i} \\ {\sum }_{i = 1}^{N} {x}_{2 i} \\ ⋮ \\ {\sum }_{i = 1}^{N} {x}_{M i}\end{matrix} ) = ( \begin{matrix}{Z}_{1} \\ {Z}_{2} \\ ⋮ \\ {Z}_{M}\end{matrix} )$$
when the multiplication data of the spectrum monitoring data of a station is required, the two-dimensional spectrum matrix of the station is processed as follows:
$$m W = ( \begin{matrix}m {x}_{11} & … & m {x}_{1 N} \\ ⋮ & ⋱ & ⋮ \\ m {x}_{M 1} & … & m {x}_{N M}\end{matrix} )$$
wherein, m is a real number.

13. The processing method of spectrum monitoring data according to claim 12, characterized in that, a geometric center point V₀ on a geographical distribution of K number of spectrum monitoring stations in an area is obtained by the following step:
$${V}_{0} = \frac{1}{K} {\sum }_{i = 1}^{K} {V}_{i}$$
where n takes the value 1, 2, 3, . . . , K; Vᵢ refers to the latitude and longitude positions of the i-th number station.

14. The processing method of spectrum monitoring data according to claim 13, characterized in that, a distance Dₙ between the latitude and longitude position Vₙ of each spectrum monitoring station and the geometric center point V₀ is obtained by the following step:
Dₙ=∥Vₙ−V₀∥₂
where ∥·∥₂ is the second-order norm operation.

15. The processing method of spectrum monitoring data according to claim 14, characterized in that, the three-dimensional frequency spectrum matrix body Q is formed by the following steps:
according to the order from small to large of the distance Dₙ between the spectrum monitoring station and the geometric center point V₀, arrange the corresponding spectrum matrix of the station to construct the three-dimensional spectrum matrix body Q=[W₁, W₂, . . . W_{K}]^{T}, the spectrum matrix body Q is in N×M×K dimension, W₁, W₂, . . . W_{K} refers to the two-dimensional spectrum matrix of K stations in an area within a given time period.

16. The processing method of spectrum monitoring data according to claim 15, characterized in that,
when the sum of the spectrum monitoring data of the stations in a multiple area is required to be obtained, the three-dimensional spectrum matrix of the stations in each area is processed as follows:
Qᵢ+Qⱼ=[W₁ⁱ+W₁^{j},W₂ⁱ+W₂^{j}, . . . W_{K}ⁱ+W_{K}^{j}]^{T}
when the difference of the spectrum monitoring data of stations in two area is required to be obtained, the three-dimensional spectrum matrix of the stations in two area is processed as follows:
Qᵢ−Qⱼ=[W₁ⁱ−W₁^{j},W₂ⁱ−W₂^{j}, . . . W_{K}ⁱ−W_{K}^{j}]^{T}
when the spectrum evaluation usage of the spectrum monitoring data of a station in a certain frequency band is required, the two-dimensional spectrum matrix of the stations in the area is processed as follows:
TProj(Q)=[TProj(W₁),TProj(W₂), . . . TProj(W_{K})]^{T}
when the spectrum evaluation usage of the spectrum monitoring data of the stations of the area in a certain frequency band is required, the three-dimensional spectrum matrix of the stations in the area is processed as follows:
FProj(Q)=[FProj(W₁),FProj(W₂), . . . FProj(W_{K})]^{T}
when the multiplication data of the spectrum monitoring data of the stations of the area in a certain frequency band is required, the three-dimensional spectrum matrix of the stations in the area is processed as follows:
mQ=[mW₁,mW₂, . . . mW_{K}]^{T}
where Qᵢ and Qⱼ are the three-dimensional spectrum matrix of stations in an area, both are N×M×K dimensions, Qᵢ=[W₁ⁱ+W₂ⁱ, . . . W_{K}ⁱ]^{T}, Qⱼ=[W₁^{j}, Q₂^{j}, . . . W_{K}^{j}]^{T}.

17. A compression processing method for spectrum monitoring data of multiple stations, characterized in that, comprising:
S1: arrange the two-dimensional spectrum matrices of multiple stations to form a three-dimensional spectrum matrix body according to the mutual relationship between the positions of the stations, wherein the two-dimensional spectrum matrix of each station is formed by the discretization of the spectrum monitoring data of the station in the time and frequency dimensions;
S2: Select one dimension from the three dimensions of the three-dimensional frequency spectrum matrix body, carrying out grayscale processing of each matrix to convert to grayscale image;
S3: compress the spectrum monitoring data in the selected dimension by using video compression method.

18. The compression processing method for spectrum monitoring data of multiple stations according to claim 17, in the step S1, the two-dimensional matrix is arranged as follows:
Selecting a station as a reference station, and arranging the spectrum matrix data corresponding to each station based on a standard of geographic straight-line distance between all stations and the reference point; or
Selecting a geographic position corresponding to the average longitude and latitude of geographic locations of multiple stations in a certain area as a reference point, and arranging the spectrum matrix data corresponding to each station based on a standard of geographic straight-line distance between all stations and the reference point; or
Selecting one particular geographic position as a reference point, and arranging the spectrum matrix data corresponding to each station based on a standard of a geographic straight-line distance between all stations and the reference point.

19. The compression processing method for spectrum monitoring data of multiple stations according to claim 17, in the step S2, the steps of gray-scale processing of the spectrum monitoring data is selected from one of the following three method:
selecting the time dimension as the reference dimension and carrying out grayscale processing on each matrix to convert each matrix into a grayscale image; or
selecting the frequency dimension as the reference dimension and carrying out grayscale processing on each matrix to convert each matrix into a grayscale image; or
selecting the position dimension as the reference dimension and carrying out grayscale processing on each matrix to convert each matrix into a grayscale image.
